(19) United States
(12) Patent Application Publication
(10) Pub. No.: US 2025/0254860 A1
(43) Pub. Date: Aug. 7, 2025

(54) SEMICONDUCTOR DEVICE

(71) Applicant: Samsung Electronics Co., Ltd., Suwon-si (KR)

(72) Inventors: Hyeran Lee, Suwon-si (KR); Taejin Park, Suwon-si (KR)

(21) Appl. No.: 18/943,200

(22) Filed: Nov. 11, 2024

(30) Foreign Application Priority Data
Feb. 7, 2024 (KR) 10-2024-0018839

(51) Int. Cl. H10B 12/00

(52) U.S. Cl. CPC H10B 12/315

(57) ABSTRACT

A semiconductor device includes a bit line, an active pattern disposed on the bit line, the active pattern connected to the bit line, a data storage structure disposed on the active pattern, the data storage structure electrically connected to the active pattern, a word line having a side surface opposing a first side surface of the active pattern, and a gate dielectric pattern between the word line and the active pattern. The word line has a downwardly recessed upper surface and an upwardly recessed lower surface.

### CROSS-REFERENCE TO RELATED APPLICATION(S)

This application claims benefit of priority to Korean Patent Application No. 10-2024-0018839 filed on Feb. 7, 2024 in the Korean Intellectual Property Office, the disclosure of which is incorporated herein by reference in its entirety.

### BACKGROUND

The present inventive concept relates to a semiconductor device and a method of forming the same.

Research has been conducted to reduce sizes of elements included in a semiconductor device and to improve performance thereof. For example, in a DRAM, research has been conducted to reliably and stably form elements having a reduced size. However, as the elements have a reduced size, semiconductor devices may be degraded.

### SUMMARY

An aspect of the present inventive concept provides a semiconductor device having an increased degree of integration and improved reliability.

Another aspect of the present inventive concept provides a method of manufacturing the semiconductor device.

According to an aspect of the present inventive concept, there is provided a semiconductor device including a bit line and an active pattern disposed on the bit line. The active pattern is electrically connected to the bit line. The semiconductor device further includes a data storage structure disposed on the active pattern, the data storage structure electrically connected to the active pattern; a word line having a side surface opposing a first side surface of the active pattern; and a gate dielectric pattern between the word line and the active pattern. The word line has a downwardly recessed upper surface and an upwardly recessed lower surface. The bit line is disposed at a level lower than that of a lower end of the active pattern, and the data storage structure is disposed at a level higher than that of a lower end of the active pattern.

According to another aspect of the present inventive concept, there is provided a semiconductor device including a bit line and a first active pattern and a second active pattern spaced apart from each other. The first and second active patterns is disposed on the bit line. The semiconductor device further includes a gate separation insulating pattern between the first active pattern and the second active pattern; a first word line between the first active pattern and the gate separation insulating pattern; a second word line between the second active pattern and the gate separation insulating pattern; a first upper gate capping insulating pattern disposed on the first word line. The first upper gate capping insulating pattern is disposed between the first active pattern and the gate separation insulating pattern. The semiconductor device further includes a second upper gate capping insulating pattern disposed on the second word line. The second upper gate capping insulating pattern is disposed between the second active pattern and the gate separation insulating pattern. The semiconductor device further includes a first lower gate capping insulating pattern disposed below the first word line. The first lower gate capping insulating pattern is between the first active pattern and the gate separation insulating pattern. The semiconductor device further includes a second lower gate capping insulating pattern disposed below the second word line. The second lower gate capping insulating pattern disposed is between the second active pattern and the gate separation insulating pattern. The semiconductor device further includes a first gate dielectric pattern disposed between the first active pattern and the first word line, between the first active pattern and the first lower gate capping insulating pattern, and between the first active pattern and the first upper gate capping insulating pattern; and a second gate dielectric pattern disposed between the second active pattern and the second word line, between the second active pattern and the second lower gate capping insulating pattern, and between the second active pattern and the second upper gate capping insulating pattern.

According to another aspect of the present inventive concept, there is provided a semiconductor device including a first conductive line; a first active pattern and a second active pattern spaced apart from each other, on the first conductive line; a gate separation insulating pattern between the first active pattern and the second active pattern; a first gate electrode between the first active pattern and the gate separation insulating pattern; a second gate electrode between the second active pattern and the gate separation insulating pattern; a first gate dielectric pattern between the first active pattern and the first gate electrode; a second gate dielectric pattern between the second active pattern and the second gate electrode; a first upper gate capping insulating pattern on an upper surface of the first gate electrode; a second upper gate capping insulating pattern on an upper surface of the second gate electrode; a first lower gate capping insulating pattern below a lower surface of the first gate electrode; and a second lower gate capping insulating pattern below a lower surface of the second gate electrode. Each of the first and second active patterns has a first source/drain region, a second source/drain region on the first source/drain region, and a vertical channel region between the first and second source/drain regions. The first gate dielectric pattern and the second gate dielectric pattern are spaced apart from each other. An upper surface of the gate separation insulating pattern is disposed at a level higher than that of an upper end of each of the first and second gate electrodes. A lower surface of the gate separation insulating pattern is disposed at a level lower than that of a lower end of each of the first and second gate electrodes.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1 to 2B are diagrams of a semiconductor device according to an example embodiment of the present inventive concept;

FIG. 3 is a cross-sectional view of a modification of a semiconductor device according to an example embodiment of the present inventive concept;

FIG. 4 is a cross-sectional view of a modification of a semiconductor device according to an example embodiment of the present inventive concept;

FIGS. 5A and 5B are diagrams of a modification of a semiconductor device according to an example embodiment of the present inventive concept;

FIG. 6 is a cross-sectional view of a modification of a semiconductor device according to an example embodiment of the present inventive concept;

FIG. 7 is a cross-sectional view of a modification of a semiconductor device according to an example embodiment of the present inventive concept;

FIGS. 8 to 17 are cross-sectional views of an example of a method for forming a semiconductor device according to an example embodiment of the present inventive concept; and

FIGS. 18 and 19 are cross-sectional views of another example of a method of forming a semiconductor device according to an example embodiment of the present inventive concept.

### DETAILED DESCRIPTION

Ordinal numbers such as “first,” “second,” “third,” etc. may be used simply as labels of certain elements, steps, etc., to distinguish such elements, steps, etc. from one another. The terms such as “first,” “second,” and “third” may be used to describe different elements, but the elements are not limited by the terms. Terms that are not described using “first,” “second,” etc., in the specification, may still be referred to as “first” or “second” in a claim (and vice versa). In addition, a term that is referenced with a particular ordinal number (e.g., “first” in a particular claim) may be described elsewhere with a different ordinal number (e.g., “second” in the specification or another claim). For example, a “first element” may be referred to as a “second element” elsewhere. For example, the terms such as “upper portion,” “intermediate portion,” and “lower portion” may be replaced with other terms, for example, “first portion,” “second portion,” and “third portion” to describe elements used herein.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. For example, as used herein, the terms such as ‘lower portion,’ ‘upper portion,’ ‘upper end,’ and ‘lower end’ may be terms described based on the drawings. It will be understood that the spatially relative terms are intended to encompass different orientations of the device in use or operation in addition to the orientation depicted in the figures. The device may be otherwise oriented (rotated 90 degrees or at other orientations) and the spatially relative descriptors used herein interpreted accordingly.

As used herein, “a vertical length of a first element” may refer to “a distance from a lower surface of the first element to an upper surface of the first element” For example, “a vertical length” may refer to a dimension measured between lower and upper surfaces in a vertical direction Z as depicted in the drawings.

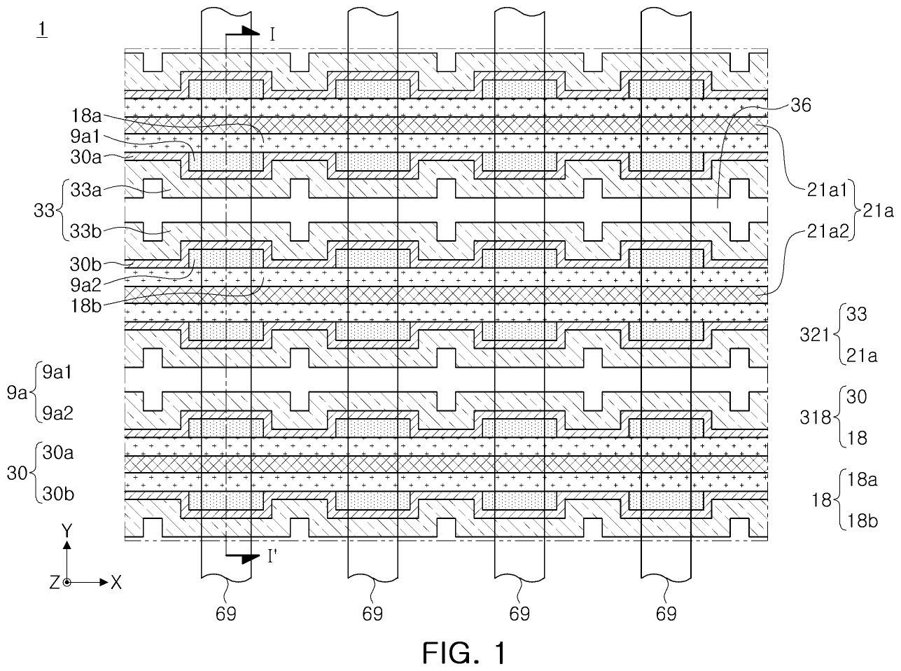

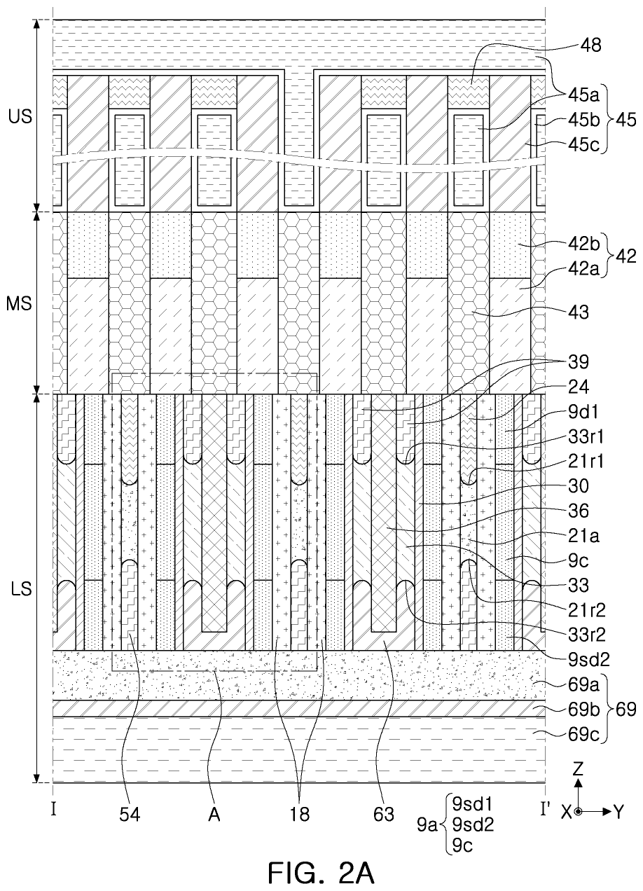

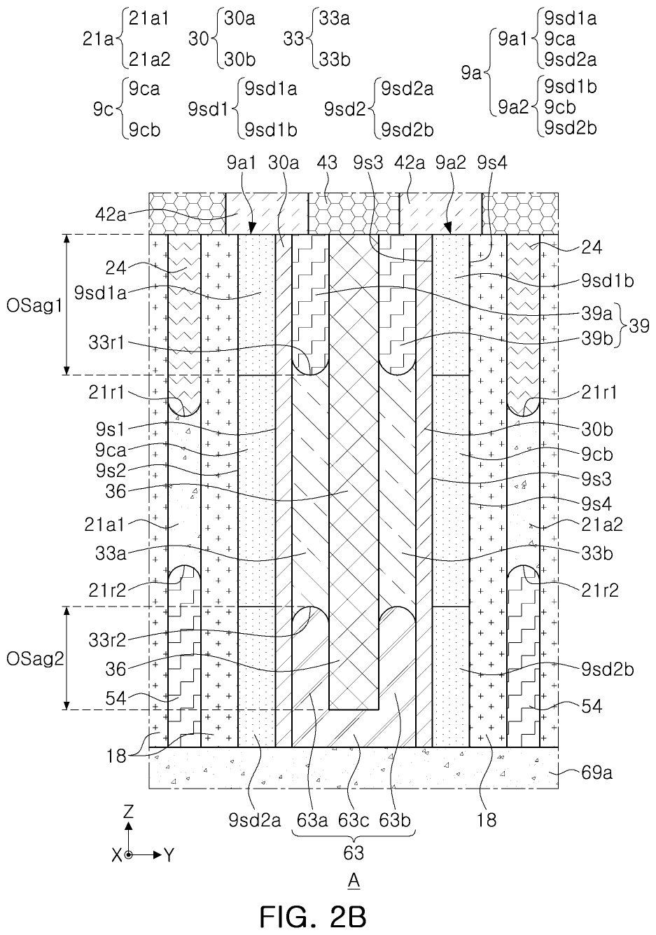

First, an example of a semiconductor device according to an example embodiment of the present inventive concept will be described with reference to FIGS. 1, 2A, and 2B. FIG. 1 is a top view of a semiconductor device according to an example embodiment of the present inventive concept, FIG. 2A is a schematic cross-sectional view of a region taken along line I-I′ of FIG. 1, and FIG. 2B is a partially enlarged view of region “A” of FIG. 2A.

Referring to FIGS. 1, 2A, and 2B, a semiconductor device 1 according to an example embodiment may include a lower structure LS, an intermediate structure MS on the lower structure LS, and an upper structure US on the intermediate structure MS.

The lower structure LS may include conductive lines 69, active patterns 9a, and gate electrodes 321. The gate electrodes 321 may include word lines (also referred to as word line gate electrodes or first gate electrodes) 33 and back gate electrodes (also referred to as second gate electrodes) 21a. The word lines 33 may include first word line gate electrodes (also referred to as first word lines) 33a and first word line gate electrodes (also referred to as second word lines) 33b. The back gate electrodes 21a may include first back gate electrodes 21a1 and second back gate electrodes 21a2.

The conductive lines 69 may be spaced apart from each other in a first horizontal direction X, and each of the conductive lines 69 may have a linear shape extending in a second horizontal direction Y, which is perpendicular to the first horizontal direction X as depicted in the drawings.

Each of the conductive lines 69 may include at least one conductive material layer. For example, each of the conductive lines 69 may include doped polysilicon, a metal, a conductive metal nitride, a metal-semiconductor compound, a conductive metal oxide, graphene, carbon nanotubes, or combinations thereof. For example, each of the conductive lines 69 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, graphene, carbon nanotubes, or combinations thereof, but the present inventive concept is not limited thereto. Each of the conductive lines 69 may include a single layer or multiple layers formed of the above-described materials. For example, each of the conductive lines 69 may include a first conductive layer 69a, a second conductive layer 69b below the first conductive layer 69a, and a third conductive layer 69c below the second conductive layer 69b. The first conductive layer 69a may include doped polysilicon having an N-type conductivity, the second conductive layer 69b may include at least one of TiN, TaN, WN, NbN, TiAl, TiAlN, TiSi, TiSiN, TaSi, TaSiN, RuTiN, NiSi, and CoSi, and the third conductive layer 69c may include at least one of Al, Cu, Ti, Ta, Ru, W, Mo, Pt, Ni, and Co.

The active patterns 9a may be disposed on the conductive lines 69. The active patterns 9a may be arranged repeatedly in the first horizontal direction X and the second horizontal direction Y. Each of the active patterns 9a may have a bar shape extending in the first horizontal direction X. Each of the active patterns 9a may have a lower source/drain region 9sd1, an upper source/drain region 9sd2 on the lower source/drain region 9sd1, and a vertical channel region 9c between the lower source/drain region 9sd1 and the upper source/drain region 9sd2.

The active patterns 9a may include a material that may be used as a channel for a transistor, for example, a semiconductor material. For example, each of the active patterns 9a may include at least one of a silicon layer, an oxide semiconductor layer, and a two-dimensional material layer having semiconductor properties. For example, each of the active patterns 9a may include single crystal silicon or polysilicon.

It should be noted that items described in the singular herein, may be provided in plural, as can be seen in the various figures from the context in which they are described. For example, hereinafter, only one of the conductive lines 69 may be described for the purpose of the brevity.

The first gate electrodes 33 may be disposed at a level higher than that of the conductive line 69. The first gate electrodes 33 may extend in a direction (i.e., direction X), intersecting the conductive line 69.

In each of the first gate electrodes 33, at least one of lower and upper surfaces may be recessed in a direction toward a middle portion between the upper and lower surfaces of the first gate electrode. For example, each of the first gate electrodes 33 may have an upwardly recessed lower surface 33r2 and a downwardly recessed upper surface 33r1.

In example embodiments, the “upwardly recessed lower surface” 33r2 may be referred to as a lower surface 33r2 having a shape recessed in a direction toward the upper surface, and the “downwardly recessed upper surface” 33r1 may be referred to as an upper surface 33r1 having a shape recessed in a direction toward the lower surface.

Each of the first gate electrodes 33 may include at least one conductive material. For example, each of the first gate electrodes 33 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or combinations thereof, but the present inventive concept is not limited thereto. Each of the first gate electrodes 33 may include a single layer or multiple layers formed of the above-described materials.

In an example embodiment, the conductive line 69 may be a bit line, and the first gate electrodes 33 may be word lines. Hereinafter, the conductive line 69 may be described as a bit line, and the first gate electrodes 33 may be described as word lines.

The active patterns 9a may include a first active pattern 9a1 and a second active pattern 9a2 spaced apart from each other in the second horizontal direction Y, on the bit line 69.

The first active pattern 9a1 may have a first lower source/drain region 9sd1a, a first upper source/drain region 9sd2a on the first lower source/drain region 9sd1a, and a first vertical channel region 9ca between the first lower source/drain region 9sd1a and the first upper source/drain region 9sd2a. The second active pattern 9a2 may have a second lower source/drain region 9sd1b, a second upper source/drain region 9sd2b on the second lower source/drain region 9sd1b, and a second vertical channel region 9cb between the second lower source/drain region 9sd1b and the second upper source/drain region 9sd2b. The first and second lower source/drain regions 9sd1a and 9sd1b may be electrically connected to the bit line 69. For example, the first and second lower source/drain regions 9sd1a and 9sd1b may be in contact with the bit line 69.

The word lines 33 may include a first word line 33a and a second word line 33b, spaced apart from each other and adjacent to each other. On the bit line 69, the first and second word lines 33a and 33b may be disposed between the first and second active patterns 9a1 and 9a2.

The lower structure LS may further include gate dielectric patterns and second gate electrodes 21a. The gate dielectric patterns may include gate dielectric patterns 30 and back gate dielectric patterns 18. The gate dielectric patterns 30 may include first gate dielectric patterns 30a and second gate dielectric patterns 30b. The back gate dielectric patterns 18 may include first back gate dielectric patterns 18a and second back gate dielectric patterns 18b.

Each of the second gate electrodes 21a may have a linear shape extending in the first horizontal direction X. Each of the second gate electrodes 21a may include at least one conductive material. For example, each of the second gate electrodes 21a may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or combinations thereof, but the present inventive concept is not limited thereto. Each of the second gate electrodes 21a may include a single layer or multiple layers formed of the above-described materials.

In example embodiments, the second gate electrodes 21a may be back gate electrodes. Hereinafter, the second gate electrodes 21a may be referred to as back gate electrodes.

In each of the back gate electrodes 21a, at least one of lower and upper surfaces may be recessed in a direction toward the middle portion between the upper and lower surfaces of the back gate electrode. For example, each of the back gate electrodes 21a may have an upwardly recessed lower surface 21r2 and a downwardly recessed upper surface 21r1.

The back gate electrodes 21a may include a first back gate electrode 21a1 and a second back gate electrode 21a2, adjacent to each other. In top view, the first and second active patterns 9a1 and 9a2 and the first and second word lines 33a and 33b may be disposed between the first back gate electrode 21a1 and the second back gate electrode 21a2.

The first active pattern 9a1 may have a first side surface 9s1 and a second side surface 9s2, opposing each other, and the second active pattern 9a2 may have a third side surface 9s3 and a fourth side surface 9s4, opposing each other. The first side surface 9s1 and the third side surface 9s3 may oppose each other.

The first word line 33a may have a side surface opposing the first side surface 9s1 of the first active pattern 9a1, and the first back gate electrode 21a1 may have a side surface opposing the second side surface 9s2 of the first active pattern 9a1. The second word line 33b may have a side surface opposing the third side surface 9s3 of the second active pattern 9a2, and the second back gate electrode 21a2 may have a side surface opposing the fourth side surface 9s4 of the second active pattern 9a2.

The gate dielectric patterns 30 may be disposed between the active patterns 9a and the word lines 33. The back gate dielectric patterns 18 may be disposed between the active patterns 9a and the back gate electrodes 21a.

The gate dielectric patterns 30 may include a first gate dielectric pattern 30a disposed between the first word line 33a and the first active pattern 9a1, and a second gate dielectric pattern 30b disposed between the second word line 33b and the second active pattern 9a2. The first lower source/drain region 9sd2a, the first vertical channel region 9ca, the first upper source/drain region 9sd1a, the first gate dielectric pattern 30a, and the first word line 33a may form a first transistor, and the second lower source/drain region 9sd2b, the second vertical channel region 9cb, the second upper source/drain region 9sd1b, the second gate dielectric pattern 30b, and the second word line 33b may form a second transistor.

Each of the back gate electrodes 21a may include at least one conductive material. For example, each of the back gate electrodes 21a may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or combinations thereof, but the present inventive concept is not limited thereto. Each of the back gate electrodes 21a may include a single layer or multiple layers formed of the above-described materials. In an example embodiment, the back gate electrodes 21a may include a conductive material different from that of the word lines 33. In another example embodiment, the back gate electrodes 21a may include a conductive material the same as that of the word lines 33.

Lower ends of the back gate electrodes 21a may be disposed at a level different from that of lower ends of the word lines 33. The lower ends of the back gate electrodes 21a may be disposed at a level higher than that of the lower ends of the word lines 33. For example, a distance between an upper surface of the bit line 69 and a lower end of the first back gate electrode 21a1 may be greater than a distance between the upper surface of the bit line 69 and a lower end of the first word line 33a.

The upper ends of the back gate electrodes 21a may be disposed at a level different from that of upper ends of the word lines 33. The upper ends of the back gate electrodes 21a may be disposed at a level lower than that of the upper ends of the word lines 33. For example, a distance between the upper surface of the bit line 69 and an upper end of the first back gate electrode 21a1 may be less than a distance between the upper surface of the bit line 69 and an upper end of the first word line 33a.

A vertical length of each of the word lines 33 may be different from a vertical length of each of the back gate electrodes 21a. The vertical length of each of the word lines 33 may be greater than the vertical length of each of the back gate electrodes 21a.

At least one of the lower source/drain region 9sd2 and the upper source/drain region 9sd1 may be disposed at a level different from that of the back gate electrodes 21a. The back gate electrodes 21a may be disposed at a level higher than that of the lower source/drain regions 9sd2. Accordingly, the lower source/drain regions 9sd2 may be prevented from being degraded by a back gate voltage applied to the back gate electrodes 21a, thereby improving performance of the semiconductor device 1.

The back gate electrodes 21a may be disposed at a level lower than that of the upper source/drain regions 9sd1. Accordingly, the upper source/drain regions 9sd1 may be prevented from being degraded by a back gate voltage applied to the back gate electrodes 21a, thereby improving performance of the semiconductor device 1.

The back gate electrodes 21a may control charges accumulated in the vertical channel regions 9c. For example, the vertical channel regions 9c may be a floating body disposed between the lower and upper source/drain regions 9sd1 and 9sd2, and the back gate electrodes 21a may suppress or prevent a floating body effect. Accordingly, the back gate electrodes 21a may minimize or prevent threshold voltages of transistors from being changed (or varied) by charges (for example, holes) being accumulated in the floating body of the vertical channel regions 9c, during operation of the transistors. Accordingly, the back gate electrodes 21a may enable the transistors to stably operate, thereby improving performance of the semiconductor device 1.

The lower structure LS may further include a gate separation insulating pattern 36. The first and second word lines 33a and 33b may be spaced apart from each other by the gate separation insulating pattern 36. Accordingly, the gate separation insulating pattern 36 may be disposed between the first and second word lines 33a and 33b. On the bit line 69, the gate separation insulating pattern 36 may be disposed between the first and second active patterns 9a.

A lower surface of the gate separation insulating pattern 36 may be disposed at a level lower than that of the lower ends of the word lines 33. An upper surface of the gate separation insulating pattern 36 may be disposed at a level higher than that of the upper ends of the word lines 33. The lower surface of the gate separation insulating pattern 36 may be disposed at a level lower than that of the vertical channel regions 9c. The upper surface of the gate separation insulating pattern 36 may be disposed at a level higher than that of the vertical channel regions 9c.

The lower structure LS may further include capping insulating patterns. The capping insulating patterns may include gate capping insulating patterns and back gate capping insulating patterns. The gate capping insulating patterns may include lower gate capping insulating patterns (also referred to as second gate capping insulating patterns) 63 and upper gate capping insulating patterns (also referred to as first gate capping insulating patterns) 39. The lower gate capping insulating patterns 63 may include first lower gate capping insulating patterns 63a and second lower gate capping insulating patterns 63b. The upper gate capping insulating patterns 39 may include first upper gate capping insulating patterns 39a and second upper gate capping insulating patterns 39b.

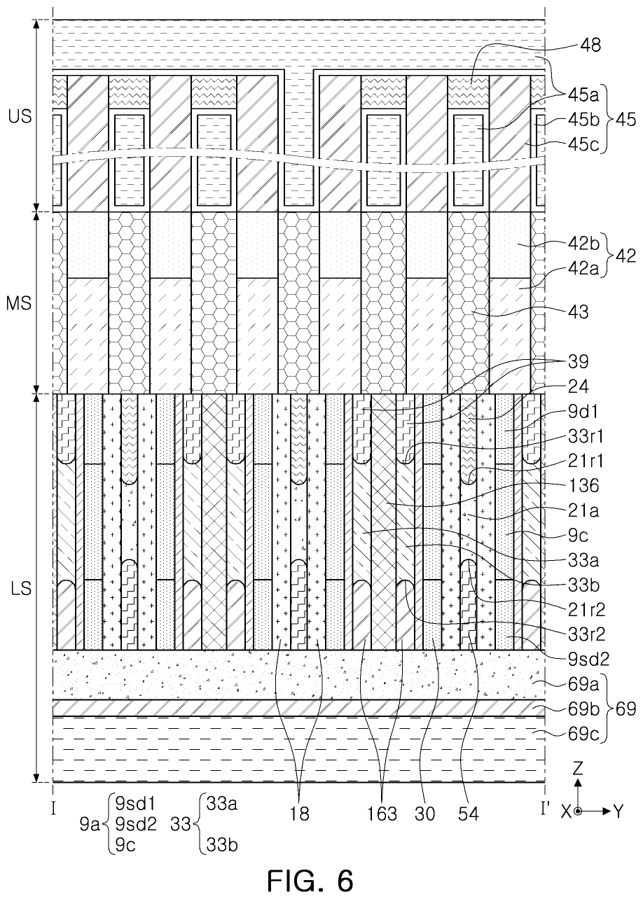

The lower gate capping insulating patterns 63 may be disposed below the word lines 33. The first lower gate capping insulating pattern 63a may be disposed below the first word line 33a. The second lower gate capping insulating pattern 63b may be disposed below the second word line 33b. The lower gate capping insulating pattern 63 may further include a third lower gate capping insulating pattern 63c, which is extending from the first lower gate capping insulating pattern 63a to the second lower gate capping insulating pattern 63b. The third lower gate capping insulating pattern 63c may be extending below the lower surface of the gate separation insulating pattern 36. In an embodiment of the invention, the first and second lower gate capping insulating patterns 63a and 63b and the third lower gate capping insulating patterns 63c may be integrally formed. In another embodiment of the invention, the first and second lower gate capping insulating patterns 63a and 63b may be spaced apart as described later in FIG. 6. For example, the first and second lower gate capping insulating patterns 63a and 63b may not be integrally formed.

An upper surface of the first lower gate capping insulating pattern 63a may be in contact with the upwardly recessed lower surface 33r2 of the first word line 33a, and an upper surface of the second lower gate capping insulating pattern 63b may be in contact with the upwardly recessed lower surface 33r2 of the second word line 33b. The third lower gate capping insulating pattern 63c may be in contact with the lower surface of the gate separation insulating pattern 36 and the upper surface of the bit line 69.

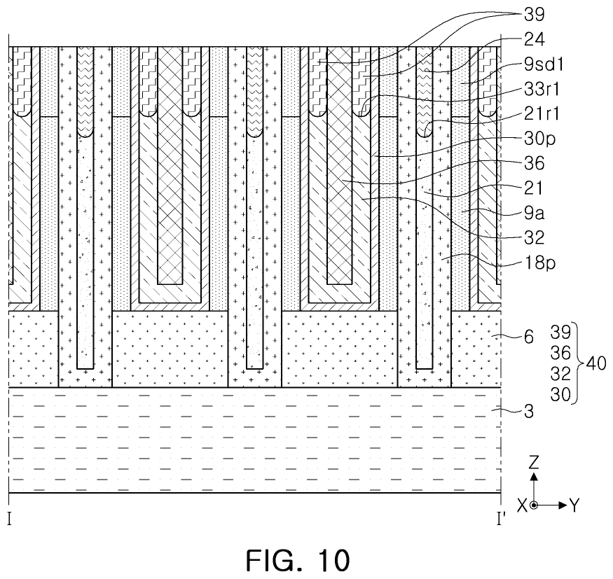

The lower structure LS may further include upper gate capping insulating patterns 39 (i.e., first gate capping insulating patterns in FIG. 10) on the word lines 33. The upper gate capping insulating patterns 39 may be referred to as second capping insulating patterns.

The upper gate capping insulating patterns 39 may include a first upper gate capping insulating pattern 39a disposed on the first word line 33a, and a second upper gate capping insulating pattern 39b disposed on the second word line 33b. The first and second upper gate capping insulating patterns 39a and 39b may be spaced apart from each other by the gate separation insulating pattern 36.

A lower surface of the first upper gate capping insulating pattern 39a may be in contact with the downwardly recessed upper surface 33r1 of the first word line 33a, and an upper surface of the second upper gate capping insulating pattern 39b may be in contact with the downwardly recessed upper surface 33r1 of the second word line 33b.

The first gate dielectric pattern 30a may extend from a portion disposed between the first active pattern 9a1 and the first word line 33a to between the first active pattern 9a1 and the first lower gate capping insulating pattern 63a, and between the first active pattern 9a1 and the first upper gate capping insulating pattern 39a. The first gate dielectric pattern 30a may be disposed between the first active pattern 9a1 and the first word line 33a, between the first active pattern 9a1 and the first lower gate capping insulating pattern 63a, and between the first active pattern 9a1 and the first upper gate capping insulating pattern 39a.

The second gate dielectric pattern 30b may extend from a portion disposed between the second active pattern 9a2 and the second word line 33b to between the second active pattern 9a2 and the second lower gate capping insulating pattern 63b, and between the second active pattern 9a2 and the second upper gate capping insulating pattern 39b. The second gate dielectric pattern 30b may be disposed between the second active pattern 9a2 and the second word line 33b, between the second active pattern 9a2 and the second lower gate capping insulating pattern 63b, and between the second active pattern 9a2 and the second upper gate capping insulating pattern 39b.

The first and second gate dielectric patterns 30a and 30b may be spaced apart from each other, and not be integrally formed.

When viewed from the side along the direction Y, the gate separation insulating patterns 36 may overlap with each of the first and second word lines 33a and 33b, and may overlap with each of the first and second active patterns 9a1 and 9a2. For example, the gate separation insulating patterns 36 may overlap with each of the first and second upper source/drain regions 9sd1a and 9sd2a as indicated by an upper overlap height OSag1. For example, the upper overlap height OSag1 may be a vertical distance between an upper end of the gate separation insulating patterns 36 and a lower end of each of the first and second upper source/drain regions 9sd1a and 9sd1b. For example, the gate separation insulating patterns 36 may overlap with each of the first and second lower source/drain regions 9sd2a and 9sd2b as indicated by an upper overlap height OSag2. One of the features of the invention may be that the lower and upper overlap heights OSag1 and OSag2 may be substantially the same as each other. Another of the features of the invention may be that the ratio of the greater one of the lower and upper overlap heights OSag1 and OSag2 to the other one may be more than 60%. Preferably, the ratio may be more than 80%. The gate separation insulating pattern 36 may be integrally formed. The lower structure LS may further include lower back gate capping insulating patterns (also referred to as second back gate capping insulating patterns) 54 disposed below the back gate electrodes 21a, and upper back gate capping insulating patterns (also referred to as first back gate capping insulating patterns) 24 disposed on the back gate electrodes 21a. The back gate dielectric patterns 18 may extend from a portion disposed between the active patterns 9a and the back gate electrodes 21a to between the active patterns 9a and the lower back gate capping insulating patterns 54, and between the active patterns 9a and the upper back gate capping insulating pattern 24.

The lower back gate capping insulating patterns 54 may be in contact with the upwardly recessed lower surfaces 21r2 of the back gate electrodes 21a. The upper back gate capping insulating patterns 24 may be in contact with the downwardly recessed upper surfaces 21r1 of the back gate electrodes 21a.

Lower surfaces of the lower back gate capping insulating patterns 54, lower surfaces of the back gate dielectric patterns 18, lower surfaces of the active patterns 9a, lower surfaces of the gate dielectric patterns 30, and a lower surface of the lower gate capping insulating pattern 63 may be in contact with the upper surface of the bit line 69.

The intermediate structure MS may include pad patterns 42 connected to the active patterns 9a, and a pad isolation insulating pattern 43 between the pad patterns 42. The pad patterns 42 may be electrically connected to the upper source/drain regions 9sd1 of the active patterns 9a.

Each of the pad patterns 42 may include at least one conductive material layer. For example, each of the pad patterns 42 may include doped silicon, a metal, a conductive metal nitride, a metal-semiconductor compound, a conductive metal oxide, conductive graphene, carbon nanotubes, or combinations thereof. For example, each of the pad patterns 42 may include doped silicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, or combinations thereof, but the present inventive concept is not limited thereto. Each of the pad patterns 42 may include a single layer or multiple layers formed of the above-described materials. For example, each of the pad patterns 42 may include a first pad layer 42a and a second pad layer 42b on the first pad layer 42a. The first pad layer 42a may include doped silicon having an N-type conductivity type, and the second pad layer 42b may include at least one of Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, and CoSi. The first pad layer 42a may include polysilicon having an N-type conductivity type or epitaxial silicon having an N-type conductivity type.

The upper structure US may include a data storage structure 45. The data storage structure 45 may be a DRAM information storage structure, for example, memory cell capacitors storing information in DRAM, but the present inventive concept is not limited thereto. For example, the data storage structure DS may be an MRAM information storage structure or a FeRAM information storage structure. For example, the data storage structure DS may be any kind of capacitor (e.g., a ferroelectric capacitor) used in a one-transistor one-capacitor (1T1C) memory cell, which is a type of memory comprising one capacitor and one transistor. For example, the data storage structure DS may be any kind of resistor including an MTJ (magnetic tunnel junction), a ferroelectric tunnel junction (FTJ) and combinations thereof used in a one-transistor one-resistor (1T1R) memory cell, which is a type of memory comprising one resistor and one transistor. For example, The data storage structure DS may be selected from the group consisting of data storage structures of a phase-change memory (PCM, PRAM, PCRAM, PC-RAM), a resistive memory (RRAM), a magnitoresistive memory (MRAM), a polymer memory (PRAM), a molecular memory, a ferroelectric memory (FeRAM), an ionic memory (PMC), a memristive memory, a spin memory, an oxide memory (such as ReRAM and 0xRAM), a conductive bridging random access memory (CBRAM), and combinations thereof.

In an embodiment of the invention, the data storage structure 45 may be a capacitor include first electrodes 45c electrically connected to the pad patterns 42, a dielectric layer 45b covering the first electrodes 45c, and a second electrode 45a covering the dielectric layer 45b. The data storage structure 45 may be electrically connected to the active patterns 9a through the pad patterns 42. For example, the second electrodes 45c of the data storage structure 45 may be electrically connected to the upper source/drain regions 9sd1 of the active patterns 9a through the pad patterns 42.

The data storage structure 45 may further include a supporter layer 48 to prevent the first and/or second electrodes 45a and 45c from collapsing or being deformed. The supporter layer 48 may be disposed between the second electrodes 45c. The dielectric layer 45b may cover the first electrodes 45a and may be in contact with the supporter layer 48.

According to an example embodiment, a vertical length and an arrangement position of the word line 33, by having the downwardly recessed upper surface 33r1 and the upwardly recessed lower surface 33r2, may be easily adjusted in a semiconductor process. Accordingly, a gate-induced-drain leakage (GIDL) current occurring between the word line 33 and the source/drain regions 9sd1 and 9sd2 may be minimized, and a transistor may have improved performance, thereby improving performance of the semiconductor device 1.

Subsequently, modified embodiments of the invention will be described, focusing on modified or substituted components with reference to the accompanying drawings. The components described earlier may be referenced directly or omitted for brevity. The modified or substituted components may be integrated with one another or with the previously described components to constitute other embodiments of the invention.

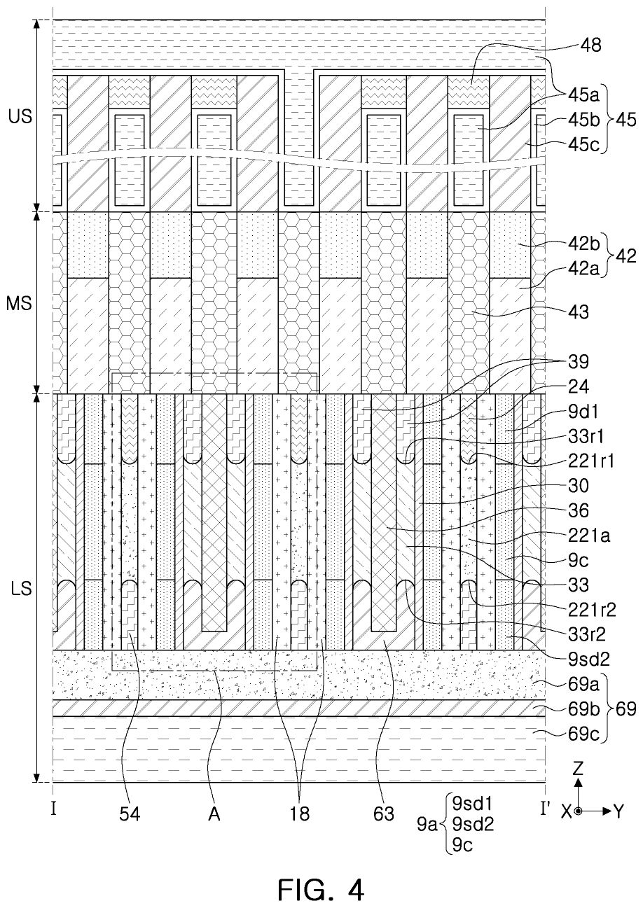

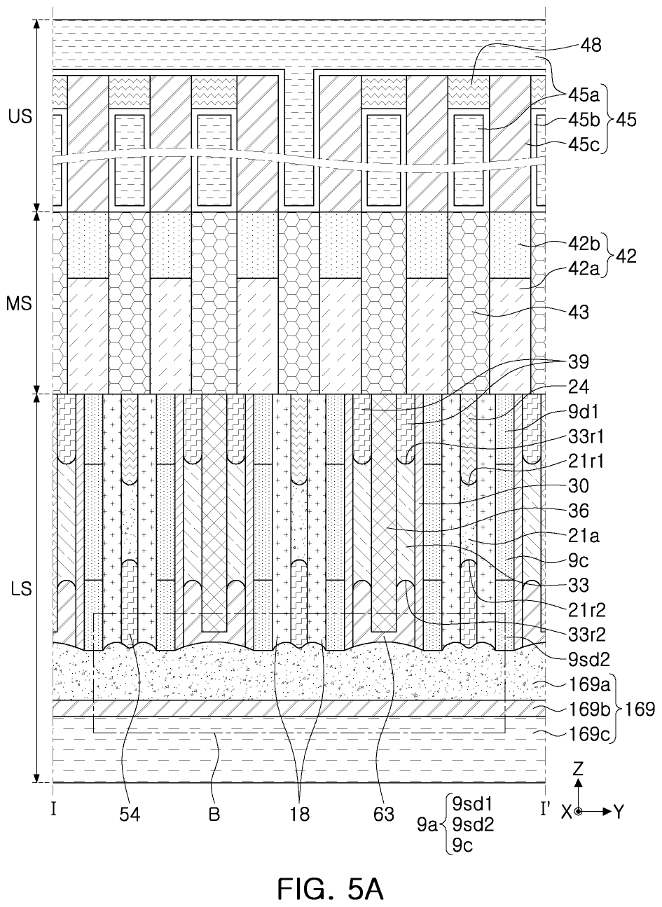

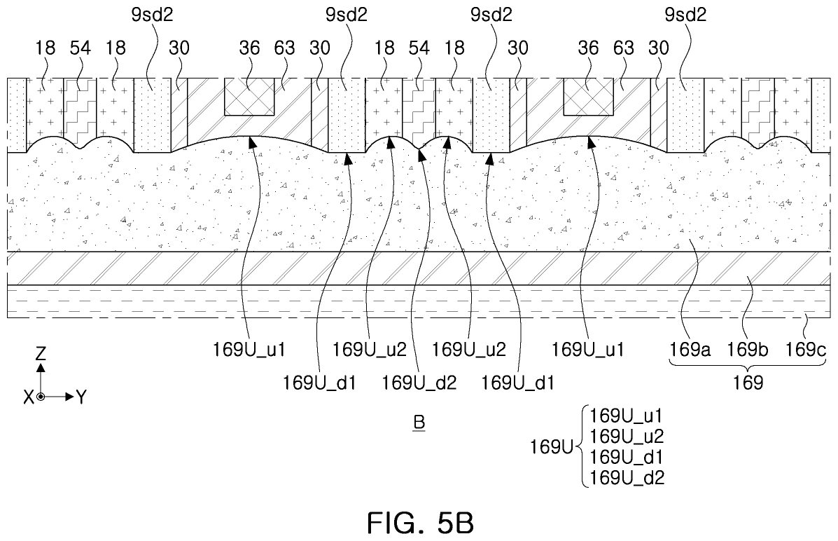

FIGS. 4, 5A, 6, and 7 are cross-sectional views taken along line I-I′ of FIG. 1 so as to describe various modifications according to example embodiments of the present inventive concept, and FIG. 5B is a partially enlarged view of region “B” of FIG. 5A.

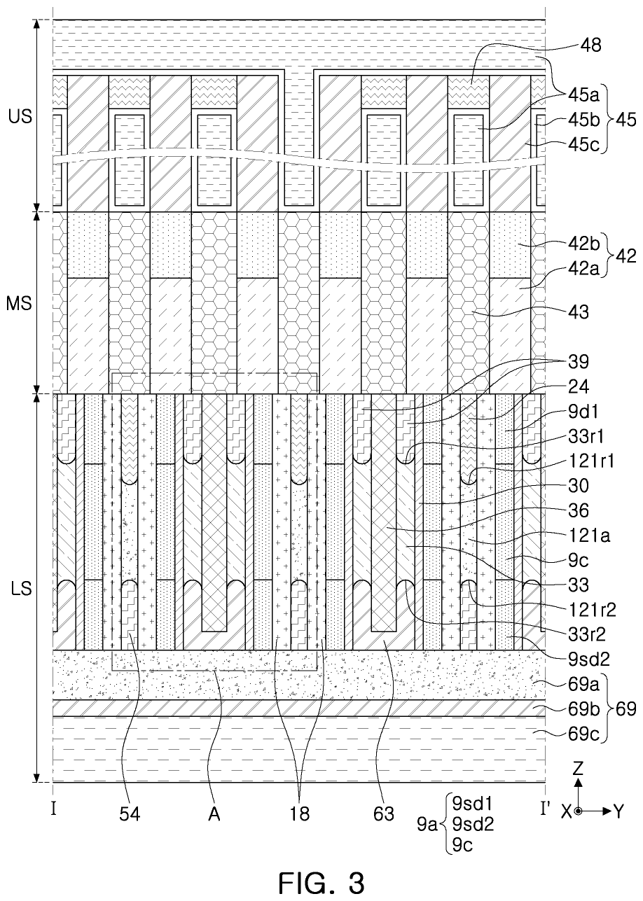

Referring to FIG. 3, the back gate electrode 21a in FIGS. 2A and 2B may be modified into a back gate electrode 121a in FIG. 3. The back gate electrode 121a may have a downwardly recessed upper surface 121r1 and an upwardly recessed lower surface 121r2. The downwardly recessed upper surface 121r1 of the back gate electrode 121a may be disposed at a level lower than that of the upper source/drain region 9sd1.

The upwardly recessed lower surface 121r2 of the back gate electrode 121a may be disposed at a level the same as or lower than that of the upwardly recessed lower surface 33r2 of the word line 33. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

For example, at least a portion of the upwardly recessed lower surface 121r2 of the back gate electrode 121a may be disposed at a level the same as that of at least a portion of the upwardly recessed lower surface 33r2 of the word line 33 as depicted in FIG. 3. Accordingly, the area where the back gate electrode 121a and the vertical channel region 9c overlap, when viewed from the side in a direction Y, may be increased. The increased area may be helpful in controlling the back gate electrode 121a with respect to the vertical channel region 9c. Accordingly, the semiconductor device may have improved performance.

Referring to FIG. 4, the back gate electrode 21a in FIGS. 2A and 2B may be modified into a back gate electrode 221a in FIG. 4. The back gate electrode 221a may have a downwardly recessed upper surface 221r1 and an upwardly recessed lower surface 221r2.

In an embodiment, the downwardly recessed upper surface 221r1 of the back gate electrode 221a may be disposed at a level the same as or higher than that of the downwardly recessed upper surface 33r1 of the word line 33. For example, at least a portion of the downwardly recessed upper surface 221r1 of the back gate electrode 221a may be disposed at a level the same as that of at least a portion of the downwardly recessed upper surface 33r1 of the word line 33 as illustrated in FIG. 4. Accordingly, the overlapping area may be further increased.

The upwardly recessed lower surface 221r2 of the back gate electrode 221a may be disposed at a level higher than, lower than or the same as that of the upwardly recessed lower surface 33r2. FIG. 4 shows that the upwardly recessed lower surface 221r2 may be disposed at a level the same as that of at least a portion of the upwardly recessed lower surface 33r2.

Referring to FIGS. 5A and 5B, in contrast to the bit line 69 having a substantially flat upper surface in FIGS. 2A and 2B, a bit line 169 may have an upper surface 169U having a wavy shape in FIGS. 5A and 5B. The bit line 169 may include first to third conductive layers 169a, 169b, and 169c corresponding to the first to third conductive layers (69a, 69b, and 69c in FIG. 2A) described above.

The upper surface 169U of the bit line 169 may have a wavy shape including downwardly concave portions 169U_d1 and 169U_d2 and upwardly convex portions 169U_u1 and 169U_u2.

In the upper surface 169U of the bit line 169, the downwardly concave portions 169U_d1 and 169U_d2 may include first concave portions 169U_d1 in contact with lower surfaces of the lower source/drain regions 9sd2 of the active patterns 9a, and second concave portions 169U_d2 in contact with lower surfaces of the second back gate capping insulating patterns 54, and the upwardly convex portions 169U_u1 and 169U_u2 may include first convex portions 169U_u1 disposed below the gate separation insulating patterns 36 and the lower gate capping insulating patterns 63, the first convex portions 169U_u1 in contact with lower surfaces of the lower gate capping insulating patterns 63, and second convex portions 169U_u2 in contact with lower surfaces of the back gate dielectric patterns 18. Portions of the upper surface 169U of the bit line 169 in contact with the active patterns 9a may have a concave shape.

The upper surface 169U of the bit line 169 may have a wavy shape, such that a contact area between a lower surface of a structure including the active patterns 9a, the second back gate capping insulating patterns 54, the lower gate capping insulating patterns 63, and the back gate dielectric patterns 18, and the upper surface 169U of the bit line 169 may be increased, thereby providing the bit line 169 reliably and stalely. Accordingly, the bit line 169 and the lower source/drain regions 9sd2 of the active patterns 9a may be in stable contact with each other without defects. Accordingly, the bit line 169 may be provided reliably.

Referring to FIG. 6, the gate separation insulating pattern 36 in FIGS. 2A and 2B and the lower gate capping insulating pattern 63 in FIGS. 2A and 2B may be modified into gate separation insulating patterns 136 and lower gate capping insulating patterns 163.

The gate separation insulating pattern 136 may have an upper surface and a lower surface. The upper surface of the gate separation insulating pattern 136 may be in contact with the pad isolation insulating pattern 43. Differently from FIGS. 2A and 2B, the lower surface of the gate separation insulating pattern 136 may be in contact with the bit line 69.

A pair of the lower gate capping insulating patterns 163 may be disposed below a pair of word lines 33a and 33b. The pair of the lower gate capping insulating patterns 163 may have lower surfaces in contact with the bit line 69. Each of the pair of the lower gate capping insulating patterns 163 may be spaced apart from each other by the gate separation insulating pattern 136. The lower gate capping insulating patterns 163 may be integrally formed.

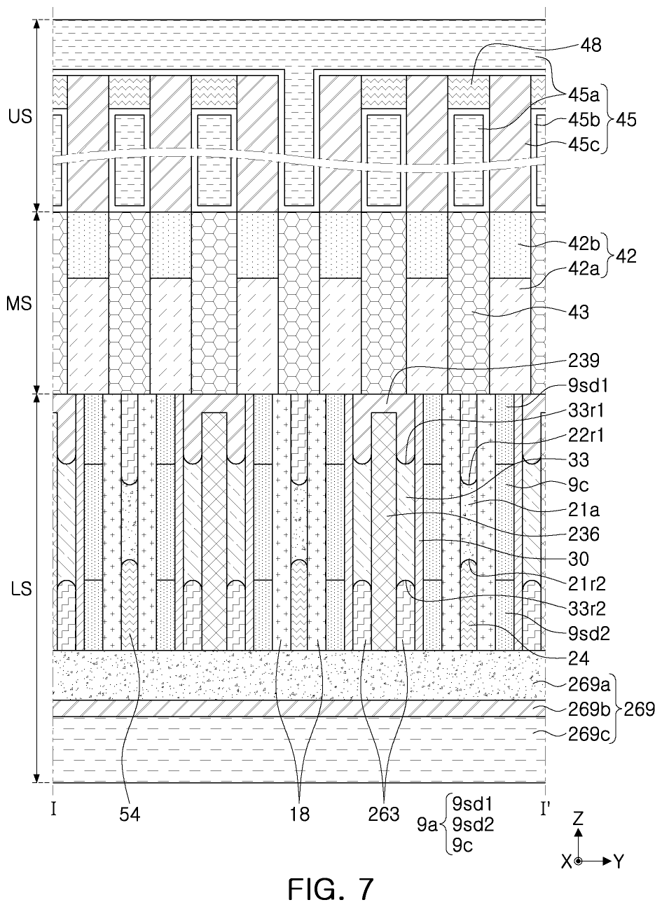

Referring to FIG. 7, the gate separation insulating pattern 36, the lower gate capping insulating pattern 63, and the upper gate capping insulating pattern 39 in FIG. 2A and 2B may be modified into a gate separation insulating pattern 236, lower gate capping insulating patterns 263, and upper gate capping insulating patterns 239.

The gate separation insulating pattern 236 may have an upper surface spaced apart from the pad isolation insulating pattern 43, and a lower surface in contact with the bit line 69.

The lower gate capping insulating patterns 263 may have a shape and a configuration substantially the same as that of the lower gate capping insulating patterns 163 described with reference to FIG. 6.

The upper gate capping insulating pattern 239 may be disposed on a pair of word lines 33a and 33b and a portion extending above an upper surface of the gate separation insulating pattern 236. Accordingly, the upper gate capping insulating pattern 239 may extend from the first word line 33a to the second word line 33b along the upper surface of the gate separation insulating pattern 236 and a lower surface of the pad isolation insulating pattern 43. For example, the upper gate capping insulating pattern 239 may have a U-shape (or shape of a reverse U). The upper gate capping insulating pattern 239 may be integrally formed. In another embodiment, the upper gate capping insulating pattern 239 may include the first and second upper gate capping insulating patterns, which are not integrally formed and may be spaced apart from each other.

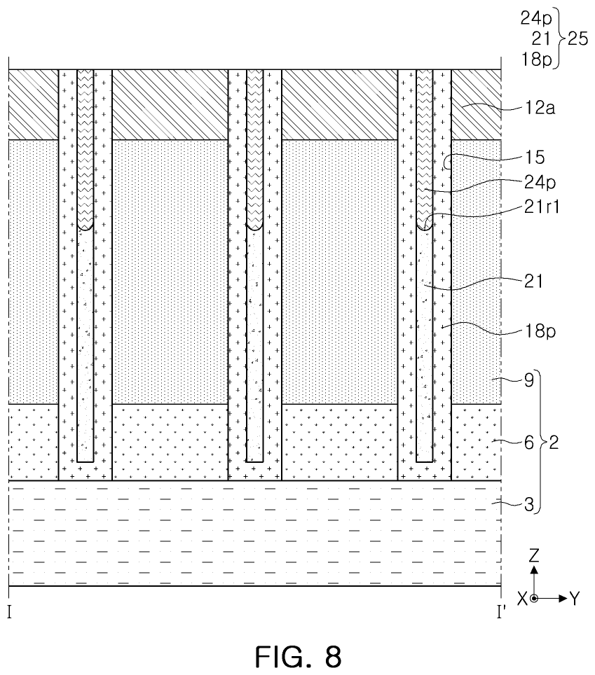

Next, with reference to FIGS. 8 to 17, an example of a method for forming a semiconductor device according to example embodiments of the present inventive concept will be described. FIGS. 8 to 17 are cross-sectional views of a region taken along line I-I′ of FIG. 1 so as to describe an example of a method of forming a semiconductor device according to example embodiments of the present inventive concept.

Referring to FIGS. 1 and 8, an insulating layer may be formed on a substrate 2 including a sacrificial substrate 3, an insulating layer 6, and a semiconductor layer, sequentially stacked. The semiconductor layer may be formed of a semiconductor material such as single crystal silicon or the like.

Trenches 15, passing through the insulating layer, the semiconductor layer, and the insulating layer 6, may be formed. Each of the trenches 15 may have a linear shape extending in a first direction X. The semiconductor layer may be patterned to form semiconductor lines 9 spaced apart from each other in a second direction Y by the trenches 15. Each of the semiconductor lines 9 may have a linear shape extending in the first direction X. The second direction Y may be perpendicular to the first direction X. The first and second directions X and Y may be perpendicular to an upper surface of the sacrificial substrate 3.

First structures 25 may be formed in the trenches 15. Forming the first structures 25 may include forming a back preliminary gate dielectric pattern 18p conformally covering inner walls of the trenches 15, forming a back gate conductive layer on the back preliminary gate dielectric pattern 18p, forming preliminary back gate electrodes 21 partially filling the trenches 15 by partially etching the back gate conductive layer using an etch-back process, and forming, on the trenches 15, first preliminary back gate capping insulating layers 24p filling remaining portions of the trenches 15.

Each of the preliminary back gate electrodes 21 may be formed to have a downwardly recessed upper surface 21r1 using the etch-back process for partially etching the back gate conductive layer. A height level of each of the downwardly recessed upper surfaces 21r1 of the preliminary back gate electrodes 21 may be determined using the etch-back process for partially etching the back gate conductive layer. For example, a vertical length of each of the preliminary back gate electrodes 21 having the downwardly recessed upper surfaces 21r1 may be determined by the extent to which the back gate conductive layer is partially removed by the etch-back process.

The downwardly recessed upper surfaces 21r1 of the preliminary back gate electrodes 21 may be formed at a level lower than that of upper surfaces of the semiconductor lines 9. Lower surfaces of the preliminary back gate electrodes 21 may be formed at a level lower than that of lower surfaces of the semiconductor lines 9.

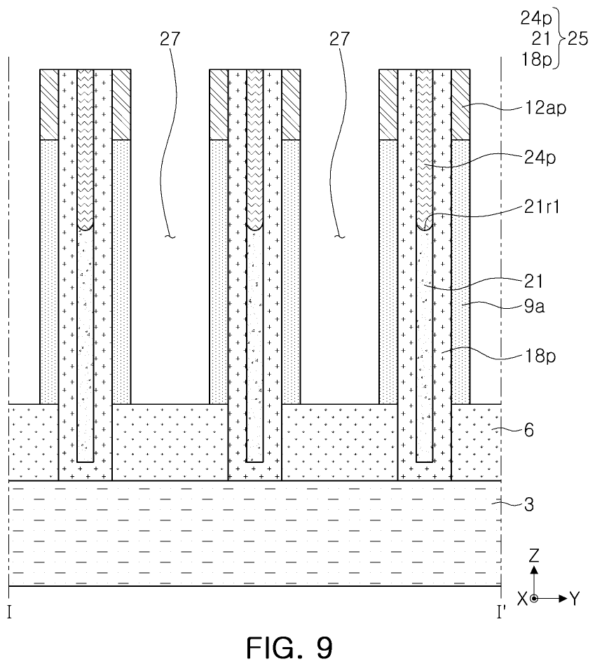

Referring to FIGS. 1 and 9, the semiconductor lines (9 in FIG. 8) may be patterned to form active patterns 9a, two-dimensionally arranged in the first direction X and the second direction Y. The insulating layer (12a in FIG. 8) may be formed of insulating patterns 12ap remaining on the active patterns 9a. The insulating patterns 12ap may serve to protect upper surfaces of the active patterns 9a during a process of patterning the semiconductor lines (9 in FIG. 8). As the active patterns 9a are formed, openings 27, exposing the insulating layer 6, may be formed between the first structures 25.

Referring to FIGS. 1 and 10, second structures 40 may be formed in the openings 27. Forming the second structures 40 may include forming a preliminary gate dielectric pattern 30p conformally covering inner walls of the openings 27, forming a gate conductive layer conformally covering the preliminary gate dielectric pattern 30p, forming gate separation insulating patterns 36 filling the openings 27 on the gate conductive layer, forming preliminary gate electrodes 32 by partially etching the gate conductive layer using an etch-back process, and forming first gate capping insulating patterns 39 on the preliminary gate electrodes 32. The preliminary gate dielectric patterns 30p may be in contact with the active patterns 9a.

Each of the preliminary gate electrodes 32 may be formed to have a downwardly recessed upper surface 33r1 by an etch-back process for partially etching the gate conductive layer.

A height level of each of the downwardly recessed upper surfaces 33r1 of the preliminary gate electrodes 32 may be determined using the etch-back process for partially etching the gate conductive layer. For example, a vertical length of each of the gate electrodes 33 having the downwardly recessed upper surfaces 33r1 may be determined by the extent to which the gate conductive layer is partially removed by the etch-back process.

Each of the second structures 40 may include the gate separation insulating pattern 36, the preliminary gate electrode 32 having a “U” shape covering side and lower surfaces of the gate separation insulating pattern 36, the first gate capping insulating patterns 39 disposed on upper surfaces of the preliminary gate electrode 32, and the preliminary gate dielectric pattern 30p covering lower and external surfaces of the preliminary gate electrode 32 and covering external surfaces of the first gate capping insulating patterns 39.

The insulating patterns 12ap and upper portion of the back preliminary gate dielectric pattern 18p may be removed. Upper portions of the first preliminary back gate capping insulating layers 24p are partially removed to form the upper back gate capping insulating patterns 24.

An ion implantation process may be performed to form first source/drain regions 9sd1 in upper regions of the active patterns 9a. The first source/drain regions 9sd1 may be referred to as upper source/drain regions.

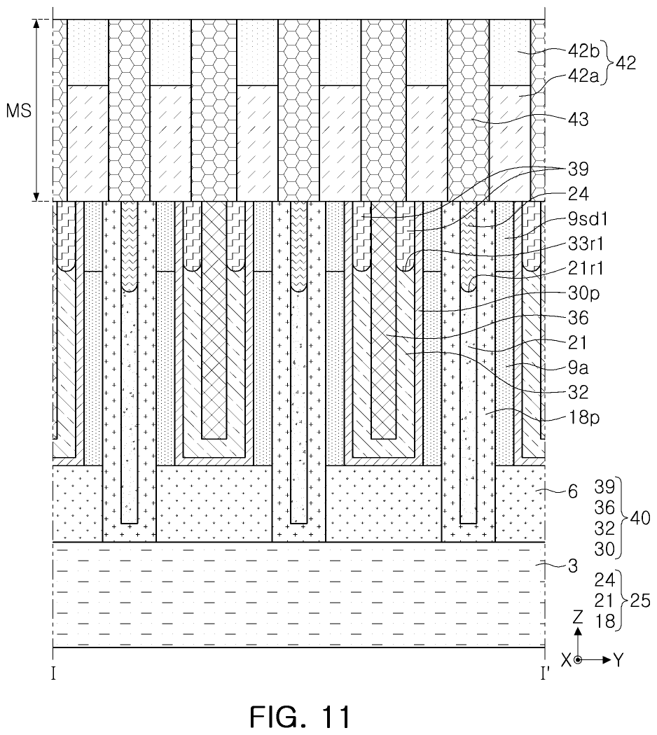

Referring to FIGS. 1 and 11, an intermediate structure MS may be formed on the second structures 40, and the active patterns 9a. The intermediate structure MS may include pad patterns 42 electrically connected to the first source/drain regions 9sd1, and a pad isolation insulating pattern 43 allowing the pad patterns 42 to be spaced apart from each other. Forming the intermediate structure MS may include forming at least one pad conductive layer, forming the pad patterns 42 by patterning the at least one pad conductive layer, and forming the pad isolation insulating pattern 43 filling a space between the pad patterns 42. Each of the pad patterns 42 may include a lower pad layer (i.e. first pad layer) 42a and an upper pad layer (i.e. second pad layer) 42b on the lower pad layer 42a, sequentially stacked.

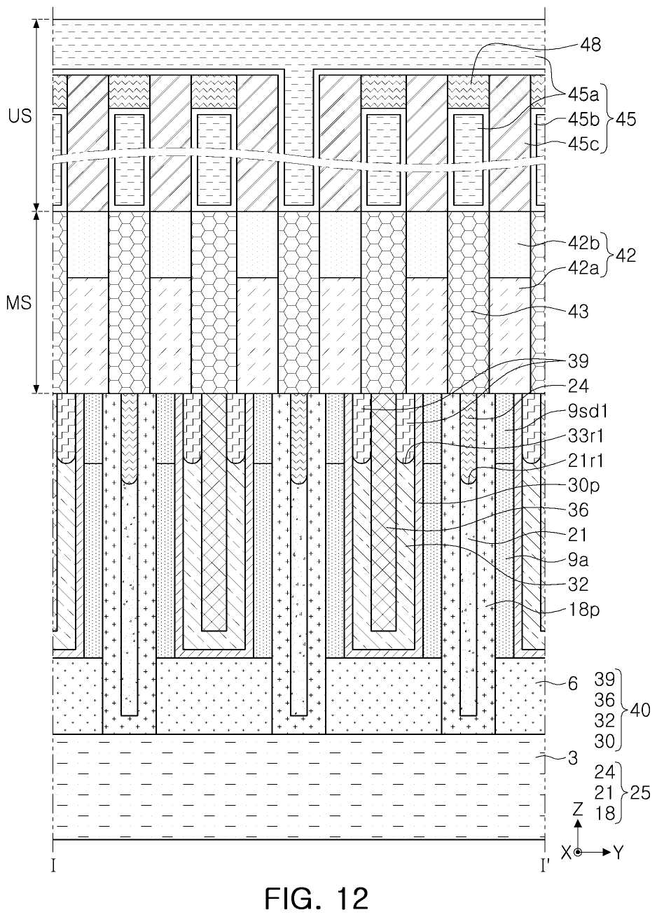

Referring to FIGS. 1 and 12, an upper structure US may be formed on the intermediate structure MS. The upper structure US may include a data storage structure 45. The information structure (i.e., data storage structure) 45 may include first electrodes 45c electrically connected to the pad patterns 42, a second electrode 45a on the first electrodes 45a, and a dielectric layer 45b between the first electrodes 45c and the second electrode 45a. The upper structure US may further include a supporter layer 48 disposed between the first electrodes 45c to prevent the first electrodes 45c from collapsing or being deformed.

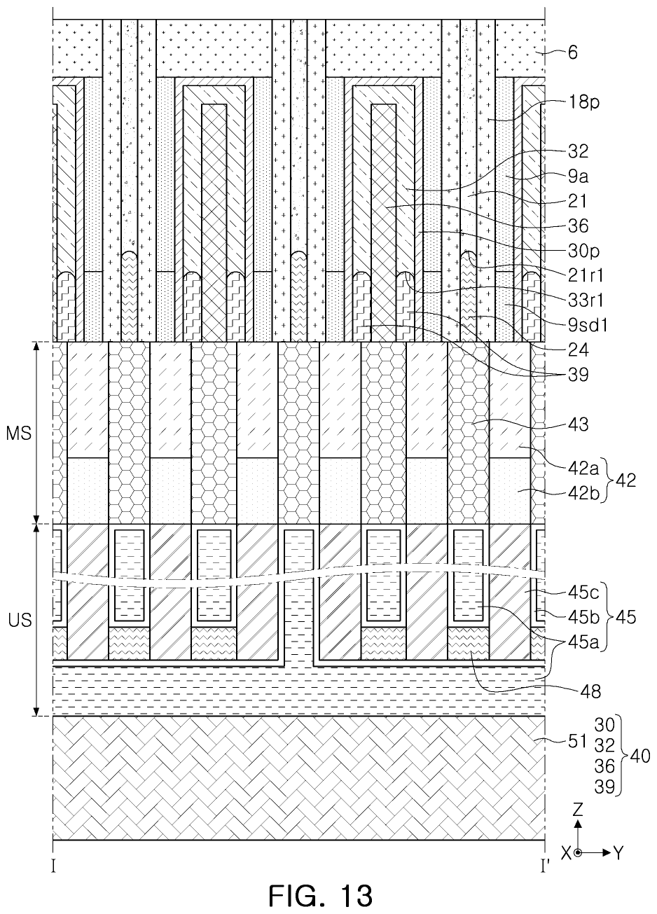

Referring to FIGS. 1 and 13, a handling wafer 51 may be formed on the upper structure US. The handling wafer 51 may be in contact with the upper structure US, and may support the upper structure US.

Then, the handling wafer 51 is positioned in a downward direction (i.e., the resulting structure is turned over), and the sacrificial substrate (3 in FIG. 12) may be removed. After the sacrificial substrate (3 in FIG. 12) is removed, a portion of the back preliminary gate dielectric pattern 18p may be removed to expose the preliminary back gate electrode 21. For example, removing the sacrificial substrate (3 in FIG. 12) may include performing a grinding process until the preliminary back gate electrode 21 is exposed.

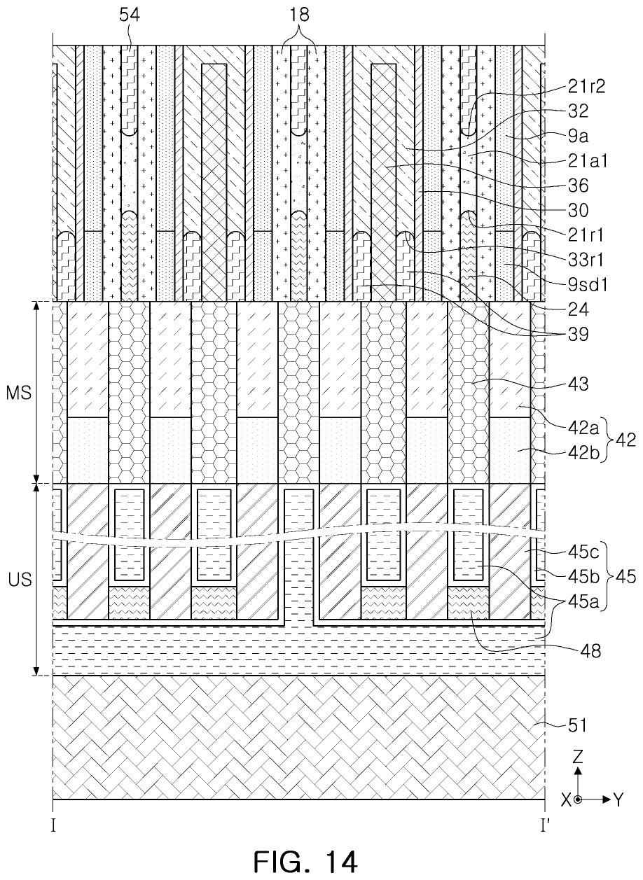

Referring to FIGS. 1 and 14, back gate electrodes 21a (i.e., 21a1 or 21a2) may be formed by partially etching the preliminary back gate electrodes 21 using an etch-back process.

Each of the back gate electrodes 21a may be formed to have recessed surfaces 21r2 using an etch-back process for partially etching the preliminary back gate electrodes (21 in FIG. 13). A height level of each of the recessed surfaces 21r2 of the back gate electrodes 21a may be determined using the etch-back process for partially etching the preliminary back gate electrodes (21 in FIG. 13), for example, a vertical length of each of the back gate electrodes 21a having the recessed surfaces 21r2 may be determined by the extent to which the preliminary back gate electrodes (21 in FIG. 13) is partially removed by the etch-back process.

The recessed surfaces 21r2 of the back gate electrodes 21a may be upper surfaces when viewed with reference to FIG. 14, but may be lower surfaces when viewed with reference to FIGS. 2A and 2B. Accordingly, the recessed surfaces 21r2 of the back gate electrodes 21a may be the upwardly recessed lower surfaces 21r2 described with reference to FIGS. 2A and 2B.

Hereinafter, the recessed surfaces 21r2 of the back gate electrodes 21a may be referred to as upwardly recessed lower surfaces 21r2.

A height level of each of the upwardly recessed lower surfaces 21r2 of the back gate electrodes 21a may be determined using the etch-back process for partially etching the preliminary back gate electrodes (21 in FIG. 13), and a height level of each of the downwardly recessed upper surfaces 21r1 of the back gate electrodes 21a may be determined by the extent to which the back gate conductive layer described above with reference to FIG. 8 is partially removed, such that a vertical length of each of the back gate electrodes 21a may be easily formed as a desired length.

Accordingly, the back gate electrodes 21a, having the downwardly recessed upper surfaces 21r1 and the upwardly recessed lower surfaces 21r2, may be formed using the etch-back process for partially etching the preliminary back gate electrodes (21 in FIG. 13), and the etch-back process for partially etching the back gate conductive layer described above with reference to FIG. 8.

Second back gate capping insulating patterns 54 may be formed on the back gate electrodes 21a. The second back gate capping insulating patterns 54 may be the lower back gate capping insulating patterns described with reference to FIGS. 2A and 2B.

In an example, forming the second back gate capping insulating patterns 54 may include depositing a capping insulating material layer, and then planarizing the capping insulating material layer until the active patterns 9a and the preliminary gate electrodes 32 are exposed.

In an example, forming the second back gate capping insulating patterns 54 may include depositing a capping insulating material layer, and then removing (e.g., etching) the capping insulating material layer. Here, a portion of the active patterns 9a and the preliminary gate electrodes 32 may be exposed using the etch-back process for partially etching the preliminary back gate electrodes 21, such that the back gate dielectric pattern 18 may be formed from the preliminary back gate dielectric pattern 18p, and may be formed gate dielectric patterns 30 from the preliminary gate dielectric patterns 30p. The condition of the etch-back process may be chosen to slightly remove at least some of the back gate dielectric patterns 18, gate dielectric patterns 30, lower gate capping insulating patterns 63, the active patterns 9a and the second back gate capping insulating patterns 54 such that the extent to which each of which are slightly removed is different to others. Accordingly, as illustrated in FIGS. 5A and 5B, the second back gate capping insulating patterns 54 and the active patterns 9a may form a protruding wavy surface using the etch-back process for partially etching the preliminary back gate electrodes 21.

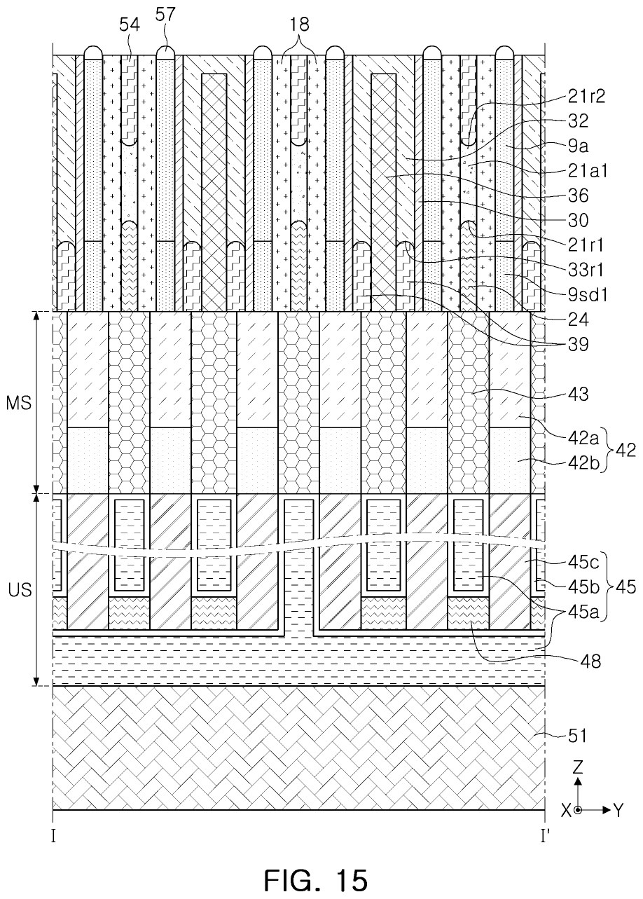

Referring to FIGS. 1 and 15, exposed surfaces of the active patterns 9a may be oxidized using an oxidation process to form oxide masks 57. For example, when the active patterns 9a are formed of single crystal silicon, the oxide masks 57 may be formed by oxidizing single crystal silicon. The oxide masks 57 may be formed of silicon oxide.

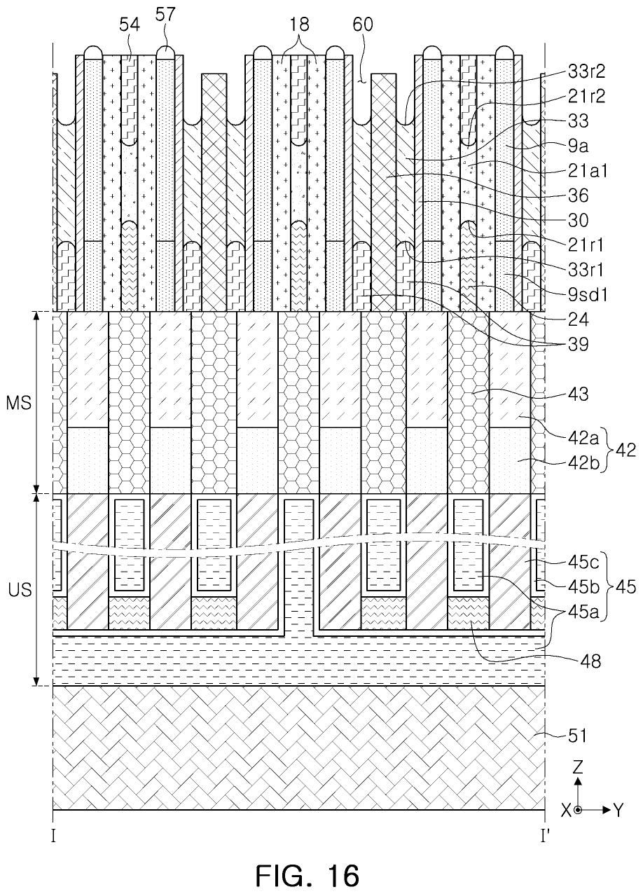

Referring to FIGS. 1 and 16, gate electrodes 33 may be formed by partially etching the preliminary gate electrodes (32 in FIG. 15) using an etch-back process. The oxide masks 57 may prevent the active patterns 9a from being damaged during an etch-back process for partially etching the preliminary gate electrodes (32 in FIG. 15).

Each of the gate electrodes 33 may have a surface 33r2 that is recessed by the etch-back process for partially etching the preliminary gate electrodes (32 in FIG. 15). The recessed surfaces 33r2 of the gate electrodes 33 may be upper surfaces when viewed with reference to FIG. 16, but may be lower surfaces when viewed with reference to FIGS. 2A and 2B. Accordingly, the recessed surfaces 33r2 of the gate electrodes 33 may be the upwardly recessed lower surfaces described with reference to FIGS. 2A and 2B.

Hereinafter, the recessed surfaces 33r2 of the gate electrodes 33 may be referred to as upwardly recessed lower surfaces 33r2.

A height level of each of the upwardly recessed lower surfaces 33r2 of the gate electrodes 33 may be determined using the etch-back process for partially etching the preliminary gate electrodes (32 in FIG. 15), and a height level of each of the downwardly recessed upper surfaces 33r1 of the gate electrodes 33 may be determined by the extent to which the gate conductive layer described above with reference to FIG. 10 is partially removed, such that a vertical length of each of the gate electrodes 33 may be easily formed as a desired length.

Accordingly, the gate electrodes 33, having the downwardly recessed upper surfaces 33r1 and the upwardly recessed lower surfaces 33r2, may be formed using the etch-back process for partially etching the preliminary gate electrodes (32 in FIG. 15), and the etch-back process for partially etching the gate conductive layer described above with reference to FIG. 10.

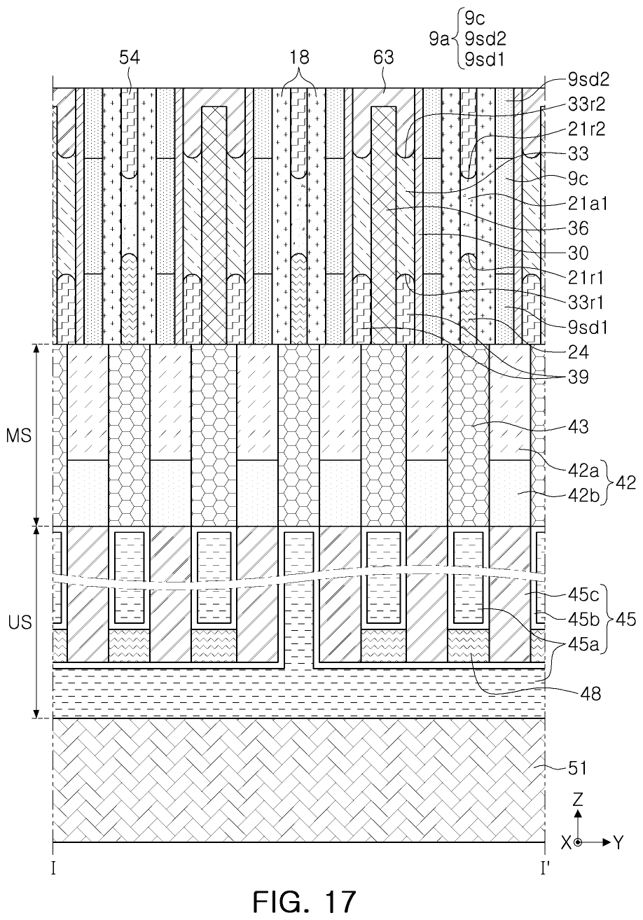

Referring to FIGS. 1 and 17, a second gate capping insulating pattern 63 may be formed on the gate electrodes 33.

In an example, the second gate capping insulating pattern 63 may be formed by forming an insulating layer on the gate electrodes 33, and planarizing the insulating layer until the active patterns 9a and the second back gate capping insulating patterns 54 are exposed. Accordingly, the second gate capping insulating pattern 63 may be formed on the gate electrodes 33, and may cover an upper surface of the gate separation insulating pattern 36.

In another example, the lower gate capping insulating patterns (163 in FIG. 6) in FIG. 6 may be formed by forming an insulating layer on the gate electrodes 33, and planarizing the insulating layer until the active patterns 9a, the second back gate capping insulating patterns 54, and the gate separation insulating pattern 36 are exposed.

While or after the second gate capping insulating pattern 63 is formed, the oxide masks 57 may be removed to expose the active patterns 9a.

An ion implantation process may be performed to form second source/drain regions 9sd2 in upper regions of the active patterns 9a. The second source/drain regions 9sd2 may be the lower source/drain regions described with reference to FIGS. 2A and 2B. Accordingly, each of the active patterns 9a may have the first source/drain region 9sd1, the second source/drain region 9sd2, and a vertical channel region 9c between the first and second source/drain regions 9sd1 and 9sd2.

Referring back to FIGS. 1, 2A, and 2B, bit lines 69 may be formed. The bit lines 69 may be electrically connected to the second source/drain regions 9sd2 of the active patterns 9a. Each of the bit lines 69 may include a first conductive layer 69a, a second conductive layer 69b on the first conductive layer 69a, and a third conductive layer 69c on the second conductive layer 69b. Thereafter, the handling wafer (51 in FIG. 17) may be removed.

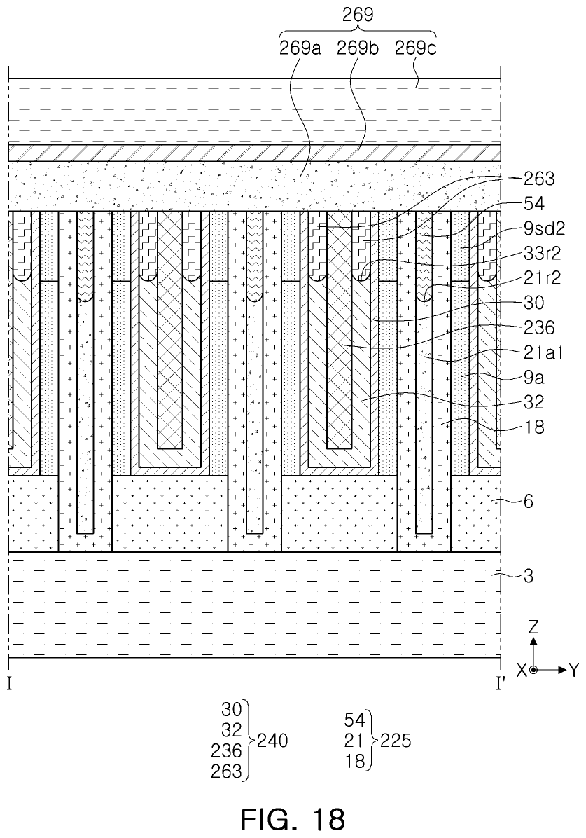

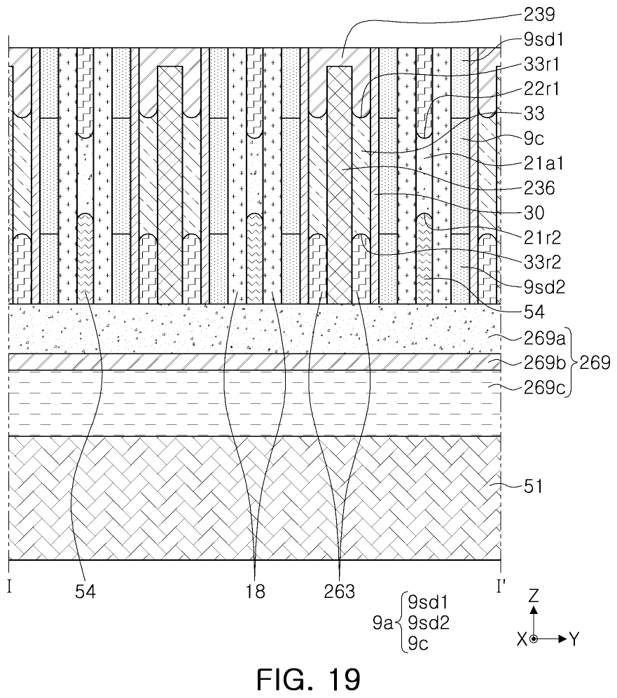

Next, with reference to FIGS. 18 and 19, another example of a method of forming a semiconductor device according to example embodiments of the present inventive concept will be described. FIGS. 18 and 19 are cross-sectional views of a region taken along line I-I′ of FIG. 1 so as to describe another example of a method of forming a semiconductor device according to example embodiments of the present inventive concept.

Referring to FIGS. 1 and 18, first structures 225 and second structures 240, having shapes substantially the same as those of the first structures 25 and the second structures 40 described with reference to FIG. 10, may be formed using a method substantially the same as that described with reference to FIGS. 8 to 10.

Each of the first structures 225 may include a back gate dielectric pattern 18, preliminary back gate electrodes 21, and back gate capping insulating patterns 54 corresponding to the back gate dielectric pattern (18 in FIG. 10), the preliminary back gate electrodes (21 in FIG. 10), and the first back gate capping insulating patterns (i.e., upper back gate capping insulating patterns 24 in FIG. 10) describe above.

Each of the second structures 240 may include a gate dielectric pattern 30, a gate separation insulating pattern 236, preliminary gate electrodes 32, and gate capping insulating patterns 263 corresponding to the gate dielectric pattern (30 in FIG. 10), the gate separation insulating pattern (36 in FIG. 10), the preliminary gate electrodes (32 in FIG. 10), and the first gate capping insulating patterns (39 in FIG. 10).

The active patterns 9a may be formed between the first structures 225 and the second structures 240. Source/drain regions 9sd2 may be formed in upper regions of the active patterns 9a formed between the first structures 225 and the second structures 240.

Bit lines 269 may be formed on the first and second structures 225 and 240 and the active patterns 9a. The bit lines 269 may be electrically connected to the source/drain regions 9sd2 of the active patterns 9a. Each of the bit lines 269 may include a first conductive layer 269a, a second conductive layer 269b, and a third conductive layer 269c, sequentially stacked.

Referring to FIGS. 1 and 19, a handling wafer 251 may be formed on the bit lines 269. Subsequently, a process substantially the same as that described with reference to FIGS. 13 to 17 may be performed to form a structure in FIG. 19.

As in the method described with reference to FIG. 13, after the handling wafer 251 is positioned in a downward direction, the sacrificial substrate (3 in FIG. 18) may be removed. As in the method described with reference to FIG. 14, back gate electrodes 21a may be formed by partially etching the preliminary back gate electrodes (21 in FIG. 18) using an etch-back process. As in the method described with reference to FIG. 14, back gate capping insulating patterns 24 may be formed on the back gate electrodes 21a.

As in the method described with reference to FIG. 15, exposed surfaces of the active patterns 9a may be oxidized using an oxidation process to form oxide masks (57 in FIG. 15). Thereafter, as in the method described with reference to FIG. 16, gate electrodes 33 may be formed by partially etching the preliminary gate electrodes (32 in FIG. 18) using an etch-back process. As in the method described with reference to FIG. 17, an upper gate capping insulating pattern 239 may be formed on the gate electrodes 33. As in the method described with reference to FIG. 17, source/drain regions 9sd1 may be formed in upper regions of the active patterns 9a by performing an ion implantation process. Accordingly, each of the active patterns 9a may have source/drain regions 9sd1 and 9sd2 spaced apart from each other in a vertical direction Z, and a vertical channel region 9c disposed between the source/drain regions 9sd1 and 9sd2.

Referring back to FIGS. 1 and 7, the intermediate structure MS is substantially the same as that described with reference to FIG. 11, and the upper structure US substantially the same as that described with reference to FIG. 12 may be sequentially formed. Subsequently, the handling wafer (251 in FIG. 19) may be removed.

According to example embodiments, a word line having at least one of an upper surface and a lower surface having a recessed shape may be provided. For example, a word line according to an example embodiment may have at least one of a downwardly recessed upper surface and an upwardly recessed lower surface. A vertical length of the word line having the downwardly recessed upper surface and the upwardly recessed lower surface may be easily adjusted in a semiconductor process, thereby minimizing gate-induced-drain leakage (GIDL) occurring between the word line and a source/drain region, and improving transistor performance.

According to example embodiments, an active pattern having a vertical channel region and a word line opposing a side surface of the active pattern may be provided, thereby increasing a degree of integration of a semiconductor device.

While example embodiments have been shown and described above, it will be apparent to those skilled in the art that modifications and variations could be made without departing from the scope of the present inventive concept as defined by the appended claims.

1. A semiconductor device comprising:
a bit line;
an active pattern disposed on the bit line, the active pattern electrically connected to the bit line;
a data storage structure disposed on the active pattern, the data storage structure electrically connected to the active pattern;
a word line having a side surface opposing a first side surface of the active pattern; and
a gate dielectric pattern between the word line and the active pattern,
wherein the word line has a downwardly recessed upper surface and an upwardly recessed lower surface,
wherein the bit line is disposed at a level lower than that of a lower end of the active pattern, and the data storage structure is disposed at a level higher than that of a lower end of the active pattern.

2. The semiconductor device of claim 1, further comprising:
a back gate electrode having a side surface opposing a second side surface of the active pattern; and
a back gate dielectric pattern between the back gate electrode and the active pattern,
wherein the first side surface and the second side surface of the active pattern oppose each other, and parallel to each other.

3. The semiconductor device of claim 2, further comprising:
a pad pattern between the data storage structure and the active pattern,
wherein the active pattern has a first source/drain region connected to the bit line, a second source/drain region connected to the pad pattern, and a vertical channel region between the first source/drain region and the second source/drain region, and
the data storage structure is electrically connected to the second source/drain region of the active pattern through the pad pattern.

4. The semiconductor device of claim 3, wherein at least one of the first and second source/drain regions is disposed at a level different from that of the back gate electrode.

5. The semiconductor device of claim 2, wherein a vertical length of the word line is greater than a vertical length of the back gate electrode.

6. The semiconductor device of claim 2, wherein a lower end of the back gate electrode is disposed at a level higher than that of a lower end of the word line.

7. The semiconductor device of claim 6, wherein an upper end of the back gate electrode is disposed at a level lower than that of an upper end of the word line.

8. The semiconductor device of claim 2, wherein the back gate electrode has a downwardly recessed upper surface and an upwardly recessed lower surface.

9. The semiconductor device of claim 8, wherein at least a portion of the upwardly recessed lower surface of the back gate electrode is disposed at a level the same as that of at least a portion of the upwardly recessed lower surface of the word line.

10. The semiconductor device of claim 8, wherein at least a portion of the downwardly recessed upper surface of the back gate electrode is disposed at a level the same as that of at least a portion of the downwardly recessed upper surface of the word line.

11. A semiconductor device comprising:
a bit line;
a first active pattern and a second active pattern spaced apart from each other, the first and second active patterns disposed on the bit line;
a gate separation insulating pattern between the first active pattern and the second active pattern;
a first word line between the first active pattern and the gate separation insulating pattern;
a second word line between the second active pattern and the gate separation insulating pattern;
a first upper gate capping insulating pattern disposed on the first word line, the first upper gate capping insulating pattern disposed between the first active pattern and the gate separation insulating pattern;
a second upper gate capping insulating pattern disposed on the second word line, the second upper gate capping insulating pattern disposed between the second active pattern and the gate separation insulating pattern;
a first lower gate capping insulating pattern disposed below the first word line, the first lower gate capping insulating pattern between the first active pattern and the gate separation insulating pattern;
a second lower gate capping insulating pattern disposed below the second word line, the second lower gate capping insulating pattern disposed between the second active pattern and the gate separation insulating pattern;
a first gate dielectric pattern disposed between the first active pattern and the first word line, between the first active pattern and the first lower gate capping insulating pattern, and between the first active pattern and the first upper gate capping insulating pattern; and
a second gate dielectric pattern disposed between the second active pattern and the second word line, between the second active pattern and the second lower gate capping insulating pattern, and between the second active pattern and the second upper gate capping insulating pattern.

12. The semiconductor device of claim 11, wherein each of the first and second word lines has an upwardly recessed lower surface and a downwardly recessed upper surface.

13. The semiconductor device of claim 11, wherein the first gate dielectric pattern and the second gate dielectric pattern are spaced apart from each other.

14. The semiconductor device of claim 11, wherein the first and second lower gate capping insulating patterns extend between a lower surface of the gate separation insulating pattern and an upper surface of the bit line.

15. The semiconductor device of claim 11, wherein the first and second upper gate capping insulating patterns extend on an upper surface of the gate separation insulating pattern.

16. The semiconductor device of claim 11, further comprising:
a first back gate electrode and a second back gate electrode spaced apart from each other;
a first back gate dielectric pattern between the first back gate electrode and the first active pattern; and
a second back gate dielectric pattern between the second back gate electrode and the second active pattern,
wherein each of the first and second back gate electrodes has a first vertical length, and
each of the first and second word lines has a second vertical length greater than the first vertical length.

17. A semiconductor device comprising:
a first conductive line;
a first active pattern and a second active pattern spaced apart from each other, the first second active patterns disposed on the first conductive line;
a gate separation insulating pattern between the first active pattern and the second active pattern;
a first gate electrode between the first active pattern and the gate separation insulating pattern;
a second gate electrode between the second active pattern and the gate separation insulating pattern;
a first gate dielectric pattern between the first active pattern and the first gate electrode;
a second gate dielectric pattern between the second active pattern and the second gate electrode;
a first upper gate capping insulating pattern on an upper surface of the first gate electrode;
a second upper gate capping insulating pattern on an upper surface of the second gate electrode;
a first lower gate capping insulating pattern below a lower surface of the first gate electrode; and
a second lower gate capping insulating pattern below a lower surface of the second gate electrode,
wherein each of the first and second active patterns has a first source/drain region, a second source/drain region on the first source/drain region, and a vertical channel region between the first and second source/drain regions,
wherein the first gate dielectric pattern and the second gate dielectric pattern are spaced apart from each other,
wherein an upper surface of the gate separation insulating pattern is disposed at a level higher than that of an upper end of each of the first and second gate electrodes, and
wherein a lower surface of the gate separation insulating pattern is disposed at a level lower than that of a lower end of each of the first and second gate electrodes.

18. The semiconductor device of claim 17, wherein each of the first and second gate electrodes has a downwardly recessed upper surface and an upwardly recessed lower surface.

19. The semiconductor device of claim 17, further comprising:
a first back gate electrode and a second back gate electrode;
a first back gate dielectric pattern between the first back gate electrode and the first active pattern; and
a second back gate dielectric pattern between the second back gate electrode and the second active pattern,
wherein the vertical channel regions of the first and second active patterns are disposed between the first and second back gate electrodes, and
a vertical length of each of the first and second word lines is greater than a vertical length of each of the first and second back gate electrodes.

20. The semiconductor device of claim 17, wherein portions of an upper surface of the first conductive line in contact with the first and second active patterns have a concave shape.

21-22. (canceled)
